(19) United States
(12) Patent Application Publication
(10) Pub. No.: US 2026/0293409 A1
(43) Pub. Date: Sep. 24, 2026

(54) ELECTRONIC DEVICE

(71) Applicant: CARUX TECHNOLOGY PTE. LTD., SINGAPORE (SG)

(72) Inventors: Szu-Yen Yu, Tainan (TW); Yen-Liang Chen, Tainan (TW)

(73) Assignee: CARUX TECHNOLOGY PTE. LTD., SINGAPORE (SG)

(21) Appl. No.: 19/466,496

(22) Filed: Feb. 1, 2026

(30) Foreign Application Priority Data
Mar. 18, 2025 (CN) 202510320443.7

(51) Int. Cl. H10H 29/855; H10H 29/85

(52) U.S. Cl. CPC H10H 29/8552; H10H 29/8506

(57) ABSTRACT

The present disclosure provides an electronic device. The electronic device includes a substrate, a blocking wall, and a light-emitting unit. The blocking wall is disposed on the substrate and has at least one opening. The light-emitting unit is disposed in the at least one opening. The light-emitting unit has a first side and a second side opposite to the first side. In a cross-section, the blocking wall has a first portion closest to the first side and a second portion closest to the second side. Along a direction perpendicular to a normal direction of the substrate, a first minimum distance from the first portion to the first side is less than a second minimum distance from the second portion to the second side.

### CROSS-REFERENCE TO RELATED APPLICATION

This application claims the priority benefit of China application serial no. 202510320443.7, filed on March 18, 2025. The entirety of the above-mentioned patent application is hereby incorporated by reference herein and made a part of this specification.

### BACKGROUND

### Technical Field

The present disclosure relates to an electronic device, and particularly relates to an electronic device that may improve the light emission efficiency of a backlight module or reduce cost.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The present disclosure is directed to an electronic device, which may improve the light emission efficiency of a backlight module or reduce cost.

According to an embodiment of the present disclosure, the electronic device includes a substrate, a blocking wall, and a light-emitting unit. The blocking wall is disposed on the substrate and has at least one opening. The light-emitting unit is disposed in the at least one opening. The light-emitting unit has a first side and a second side opposite to the first side. In a cross-section, the blocking wall has a first portion closest to the first side and a second portion closest to the second side. Along a direction perpendicular to a normal direction of the substrate, a first minimum distance from the first portion to the first side is less than a second minimum distance from the second portion to the second side.

According to an embodiment of the present disclosure, the electronic device includes a substrate, a blocking wall, and a light-emitting unit. The blocking wall is disposed on the substrate and has at least one opening. The light-emitting unit is disposed in the at least one opening. The light-emitting unit has a first side and a second side opposite to the first side. In a cross-section, the blocking wall has a first portion closest to the first side and a second portion closest to the second side. Along a reference line perpendicular to a normal direction of the substrate, an absolute value of a slope at an intersection between a side surface of the first portion facing the light-emitting unit and the reference line is less than an absolute value of a slope at an intersection between a side surface of the second portion facing the light-emitting unit and the reference line.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a top schematic view of an electronic device according to a first embodiment of the present disclosure.

FIG. 1B is a cross-sectional schematic view of the electronic device of FIG. 1A along a cross-sectional line I-I'.

FIG. 1C illustrates the operating principle of the blocking wall in the electronic device of FIG. 1B.

FIG. 1D is a cross-sectional schematic view of a method for manufacturing the electronic device of FIG. 1B.

FIG. 2 is a cross-sectional schematic view of a method for manufacturing an electronic device according to a second embodiment of the present disclosure.

FIG. 3 is a cross-sectional schematic view of an electronic device according to a third embodiment of the present disclosure.

FIG. 4 is a cross-sectional schematic view of an electronic device according to a fourth embodiment of the present disclosure.

FIG. 5 is a cross-sectional schematic view of an electronic device according to a fifth embodiment of the present disclosure.

FIG. 6 is a cross-sectional schematic view of an electronic device according to a sixth embodiment of the present disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

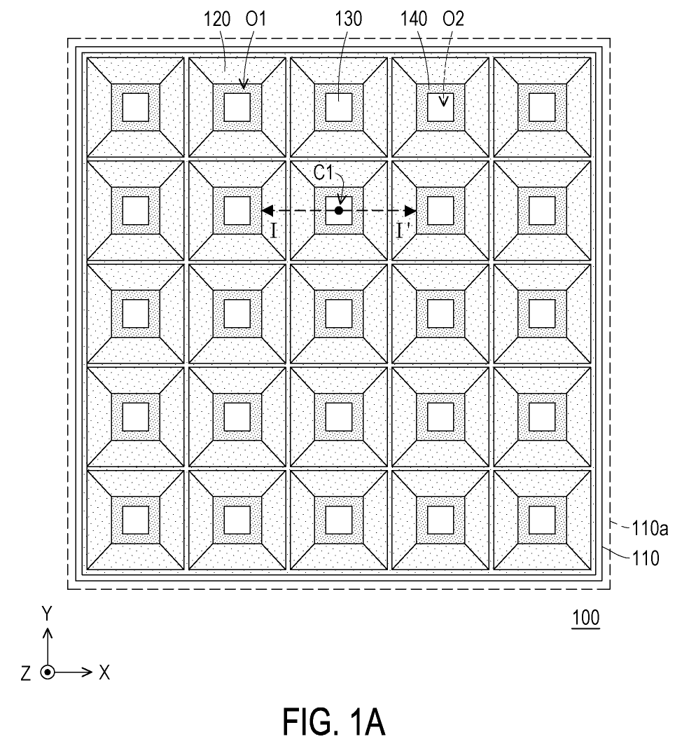

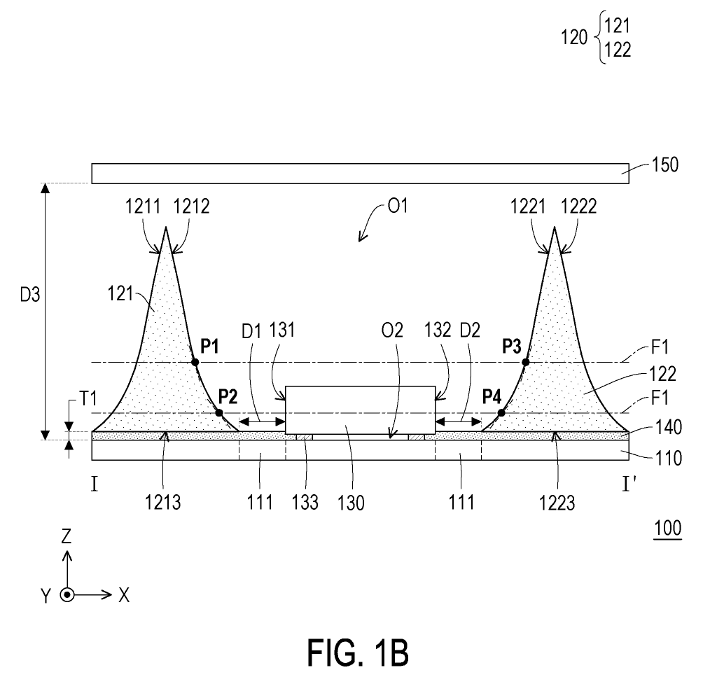

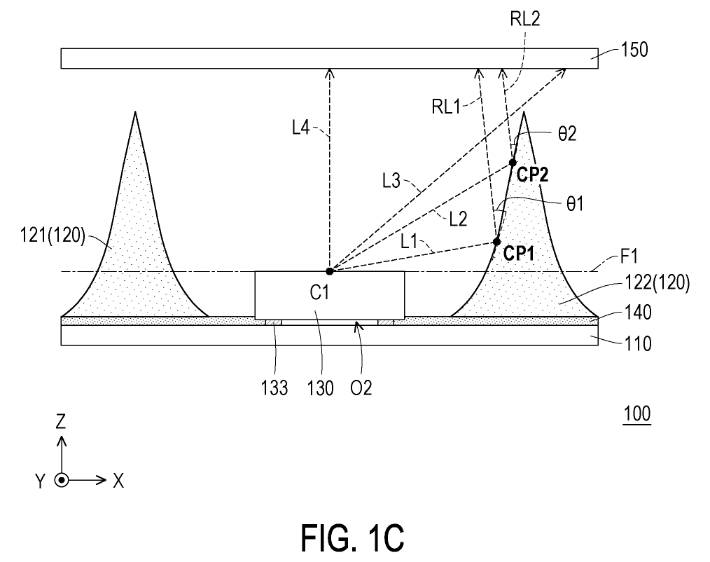

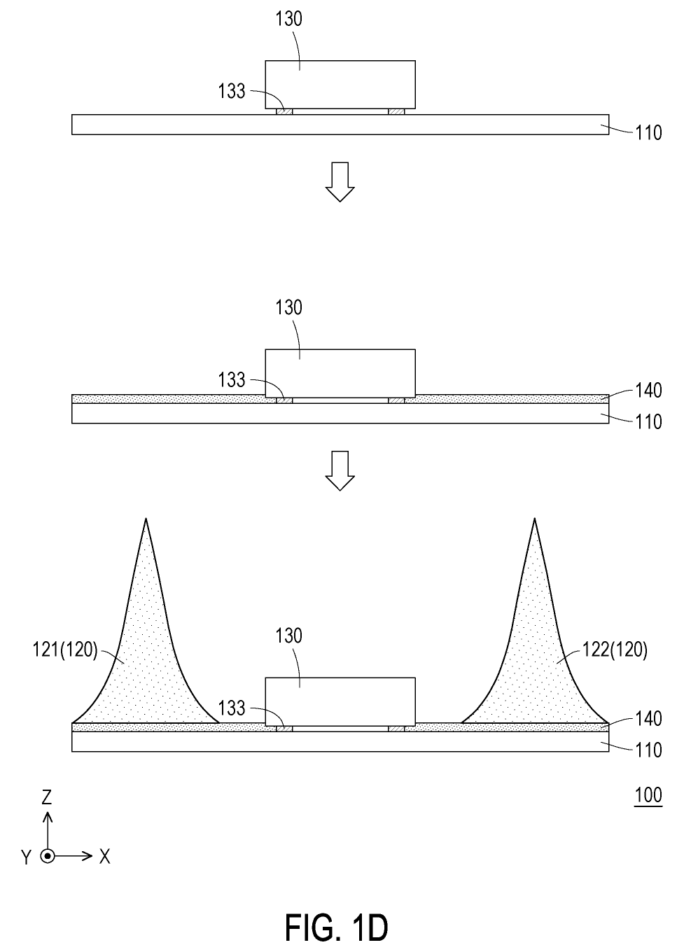

FIG. 1A is a top schematic view of an electronic device according to a first embodiment of the present disclosure. FIG. 1B is a cross-sectional schematic view of the electronic device of FIG. 1A along a cross-sectional line I-I'. The cross-sectional line I-I' is parallel to a direction X, which is perpendicular to a normal direction Z of the substrate 110, and passes through a center point C1 of the light-emitting unit 130. In some embodiments, when the substrate has an arbitrary shape, a minimum virtual rectangle enclosing the shape of the substrate may be defined, the side with the minimum side length of the minimum virtual rectangle is the reference side, and the direction parallel to the extending direction of the reference side is the direction X. When the minimum virtual rectangle is a square, the side with the smallest length may be any side. Taking FIG. 1A as an example, the minimum virtual rectangle 110a enclosing the substrate 110 is a square, so the direction X is defined by taking the lower side of FIG. 1A as the reference side. In some embodiments, when the light-emitting unit has an arbitrary shape, a minimum virtual rectangle enclosing the shape of the light-emitting unit may be defined, and the geometric center of the minimum virtual rectangle may be regarded as the center point of the light-emitting unit. The geometric center may be the intersection of the diagonals of the minimum virtual rectangle. Taking FIG. 1A as an example, a minimum virtual rectangle (not shown) enclosing the light-emitting unit 130 may be defined, and the geometric center at the intersection of diagonals of the minimum virtual rectangle is the center point C1. FIG. 1C illustrates the working principle of the blocking wall in the electronic device of FIG. 1B. FIG. 1D is a cross-sectional schematic view of a method for manufacturing the electronic device of FIG. 1B. For the sake of clarity and convenience of description, some elements of an electronic device 100 are omitted in FIG. 1A (for example, substrate 110 and diffuser plate 150).

Please refer to FIG. 1A to FIG. 1D, the electronic device 100 of the present embodiment includes a substrate 110, a blocking wall 120, a light-emitting unit 130, a reflective material layer 140, and a diffuser plate 150.

Specifically, the substrate 110 may include a carrier and a circuit layer disposed on the carrier, and the substrate 110 may be used to drive the light-emitting unit 130. In the present embodiment, the carrier may include a rigid carrier, a flexible carrier, or a combination thereof. For example, the material of the carrier may include glass, quartz, sapphire, ceramic, polycarbonate (PC), polyimide (PI), polyethylene terephthalate (PET), other suitable materials, or combinations thereof, but is not limited thereto. The circuit layer may includes a combination of at least one insulating layer and at least one conductive layer, and the circuit layer may be used to conduct electrical signals.

The blocking wall 120 is disposed on the substrate 110. The blocking wall 120 has at least one opening O1. In the cross-section shown in FIG. 1B, the light-emitting unit 130 is disposed in the opening O1 and disposed between the blocking walls 120. The blocking wall 120 has a first portion 121 and a second portion 122, which are respectively closest to two opposite sides of the light-emitting unit 130 in the opening O1. The first portion 121 has a side surface 1211, another side surface 1212, and a bottom surface 1213, and the second portion 122 has a side surface 1221, another side surface 1222, and a bottom surface 1223. The side surface 1211 connects to the another side surface 1212, the another side surface 1212 faces the light-emitting unit 130 and the side surface 1221, the bottom surface 1213 connects the side surface 1211 and the another side surface 1212, and the bottom surface 1213 faces the substrate 110. The side surface 1221 connects to the another side surface 1222, the side surface 1221 faces the light-emitting unit 130 and the another side surface 1212, the bottom surface 1223 connects the side surface 1221 and the another side surface 1222, and the bottom surface 1223 faces the substrate 110. In the present embodiment, the blocking wall 120 may be formed by injection molding plastic or silicone, but is not limited thereto.

In the present embodiment, the side surface 1211 and the another side surface 1212 of the first portion 121 may be curved surfaces, and the side surface 1221 and the another side surface 1222 of the second portion 122 may also be curved surfaces, but are not limited thereto. The absolute value of the slope of the side surface 1211 and the absolute value of the slope of the another side surface 1212 of the first portion 121 may gradually decrease from one end far from the substrate 110 toward the another end adjacent to the substrate 110, and the absolute value of the slope of the side surface 1221 and the absolute value of the slope of the another side surface 1222 of the second portion 122 may also gradually decrease from one end far from the substrate 110 toward the another end adjacent to the substrate 110, but are not limited thereto. In the present embodiment, the slope of the curved surface is the slope of the tangent at any point on the curved surface, and the slope at any point on the curved surface is different.

In the present embodiment, as shown in the cross-section of FIG. 1B, along the same reference line (for example, the reference line F1 parallel to the direction X perpendicular to the normal direction Z of the substrate), the absolute value of the slope of the side surface 1211 of the first portion 121 may be equal to the absolute value of the slope of the another side surface 1212, the absolute value of the slope of the side surface 1221 of the second portion 122 may be equal to the absolute value of the slope of the another side surface 1222, and the absolute value of the slope of the another side surface 1212 of the first portion 121 may be equal to the absolute value of the slope of the side surface 1221 of the second portion 122, but is not limited thereto. Furthermore, in the present embodiment, the curvature of the side surface 1211 of the first portion 121 may be equal to the curvature of the another side surface 1212, the curvature of the side surface 1221 of the second portion 122 may be equal to the curvature of the another side surface 1222, and the curvature of the another side surface 1212 of the first portion 121 may be equal to the curvature of the side surface 1221 of the second portion 122, but is not limited thereto.

The light-emitting unit 130 is disposed on the substrate 110 within at least one opening O1 of the blocking wall 120, and the light-emitting unit 130 may expose a portion 111 of the substrate 110 within the opening O1. The light-emitting unit 130 has a first side 131 and a second side 132 opposite to each other. The first side 131 faces the first portion 121 of the blocking wall 120, and the second side 132 faces the second portion 122 of the blocking wall 120. The light-emitting unit 130 may be electrically connected to the substrate 110 through a pad 133.

In this embodiment, along the direction X perpendicular to the normal direction Z of the substrate 110, there is a first minimum distance D1 between the first portion 121 and the light-emitting unit 130, and there is a second minimum distance D2 between the light-emitting unit 130 and the second portion 122. In the normal direction Z of the substrate 110, there is a third minimum distance D3 between the diffuser plate 150 and the substrate 110. Herein, the first minimum distance D1 may be the minimum distance measured along the direction X between the another side surface 1212 of the first portion 121 and the first side 131 of the light-emitting unit 130, the second minimum distance D2 may be the minimum distance measured along the direction X between the second side 132 of the light-emitting unit 130 and the side surface 1221 of the second portion 122, and the third minimum distance D3 may be the minimum distance measured along the normal direction Z of the substrate 110 between the diffuser plate 150 and the substrate 110.

In this embodiment, the first minimum distance D1 and the second minimum distance D2 may be greater than or equal to 10 micrometers (μm), the first minimum distance D1 may be equal to the second minimum distance D2, and the first minimum distance D1 and the second minimum distance D2 may be less than 6 times the third minimum distance D3 (that is, D1, D2, and D3 may satisfy the following formula: 10μm ≤ D1 = D2 < 6×D3), but is not limited thereto. In some embodiments, when the first minimum distance D1 or the second minimum distance D2 is less than 6 times the third minimum distance D3, the light emitted by the light-emitting unit 130 in the opening O1 and another light-emitting unit 130 in another adjacent opening O1 will not cause dark regions or brightness reduction due to the blocking wall 120 between openings O1 after passing through the diffuser plate 150, thereby improving the uneven display brightness (mura) between adjacent openings O1. When the first minimum distance D1 and the second minimum distance D2 may be greater than or equal to 10 micrometers, it may reduce the problem of damage to the light-emitting unit caused by accidental collision during assembly of the blocking wall, or may reduce the problem of damage to the light-emitting unit caused by collision during thermal expansion of the blocking wall. In addition, in some embodiments, the third minimum distance D3 between the diffuser plate 150 and the substrate 110 may range from 1 millimeter (mm) to 8 millimeters, but is not limited thereto.

The reflective material layer 140 is disposed on the substrate 110, and the reflective material layer 140 may be disposed between the blocking wall 120 and the substrate 110. The reflective material layer 140 may cover the portion 111 of the substrate 110 that is not covered by the blocking wall 120 and the light-emitting unit 130, and the reflective material layer 140 may cover the pad 133, thereby improving the light emission efficiency of the light-emitting unit 130 or reducing cost (for example, reducing the cost of increasing current for enhancing the brightness of the light-emitting unit 130, but is not limited thereto). The reflective material layer 140 has an opening O2, and the opening O2 may overlap with the light-emitting unit 130 in the normal direction Z of the substrate 110. In the present embodiment, in the normal direction Z of the substrate 110, the reflective material layer 140 may overlap with the blocking wall 120 and a portion of the opening O1, but is not limited thereto.

In the present embodiment, the thickness T1 of the reflective material layer 140 may be from 50 micrometers to 150 micrometers, but is not limited thereto. Herein, the thickness T1 may be the thickness of the reflective material layer 140 measured along the normal direction Z of the substrate 110. In the present embodiment, the material of the reflective material layer 140 may include white silicon glue or other suitable highly reflective materials, and the reflectivity of the reflective material layer 140 may be from 90% to 95%, but is not limited thereto.

The diffuser plate 150 is disposed on the blocking wall 120. In the normal direction Z of the substrate 110, the diffuser plate 150 may overlap with the light-emitting unit 130.

Please continue to refer to FIG. 1C, in the present embodiment, when the light-emitting unit 130 emits light from its center point C1, the light ray with higher emission angles (for example, the light ray with emission angles from 40 degrees to 90 degrees, but is not limited thereto) may directly proceed toward the diffuser plate 150; whereas the light ray with lower emission angles (for example, the light ray with emission angles from 10 degrees to 35 degrees, but is not limited thereto) need to first irradiate onto the blocking wall 120 and be reflected by the blocking wall 120, and subsequently, these reflected light proceed toward the diffuser plate 150. In other words, in the present embodiment, by disposing the blocking wall 120, the light ray with lower emission angles may be utilized to enhance the light emission efficiency of the light-emitting unit 130. In the present embodiment, the emission angle refers to the angle between the reference line F1 passing through the center point C1 and the light ray emitted from the center point C1. As shown in FIG. 1C, the light ray with an emission angle of 40 degrees is the light ray L3.

In the present embodiment, the angles (for example, angle θ1, angle θ2) between the tangent at the contact points on the blocking wall 120 irradiated by any light rays with lower emission angle and their reflected light rays may be identical, so that these light rays with lower emission angle may be reflected toward the diffuser plate 150 at the same angle, thereby enhancing the brightness at specific emission angles. The angles of the aforementioned angles (for example, angle θ1, angle θ2) may range from 20 degrees to 80 degrees, or from 30 degrees to 75 degrees, but are not limited thereto. For example, the angle between the tangent at the contact point CP1 on the blocking wall 120 irradiated by the light ray L1 with an emission angle of 10 degrees and its reflected light ray RL1 is θ1, and the angle between the tangent at the contact point CP2 on the blocking wall 120 irradiated by the light ray L2 with an emission angle of 30 degrees and its reflected light ray RL2 is θ2, wherein the angle θ1 may be equal to the angle θ2.

Please continue to refer to FIG. 1D, in the present embodiment, the method of manufacturing the electronic device 100 may include, but is not limited to, the following steps: First, providing a substrate 110 and disposing a light-emitting unit 130 on the substrate 110, wherein the light-emitting unit 130 may expose a portion of the substrate 110. Next, forming a reflective material layer 140 on the substrate 110, so that the reflective material layer 140 may cover the portion of the substrate 110 exposed by the light-emitting unit 130. Finally, disposing a blocking wall 120 on the substrate 110 and the reflective material layer 140. At this point, the electronic device 100 of the present embodiment has been substantially manufactured.

In some embodiments, when forming the reflective material layer 140 on the substrate 110, the reflective material layer 140 may further penetrate between the light-emitting unit 130 and the substrate 110, such that the reflective material layer 140 may overlap with a portion of the light-emitting unit 130 in the normal direction Z of the substrate 110.

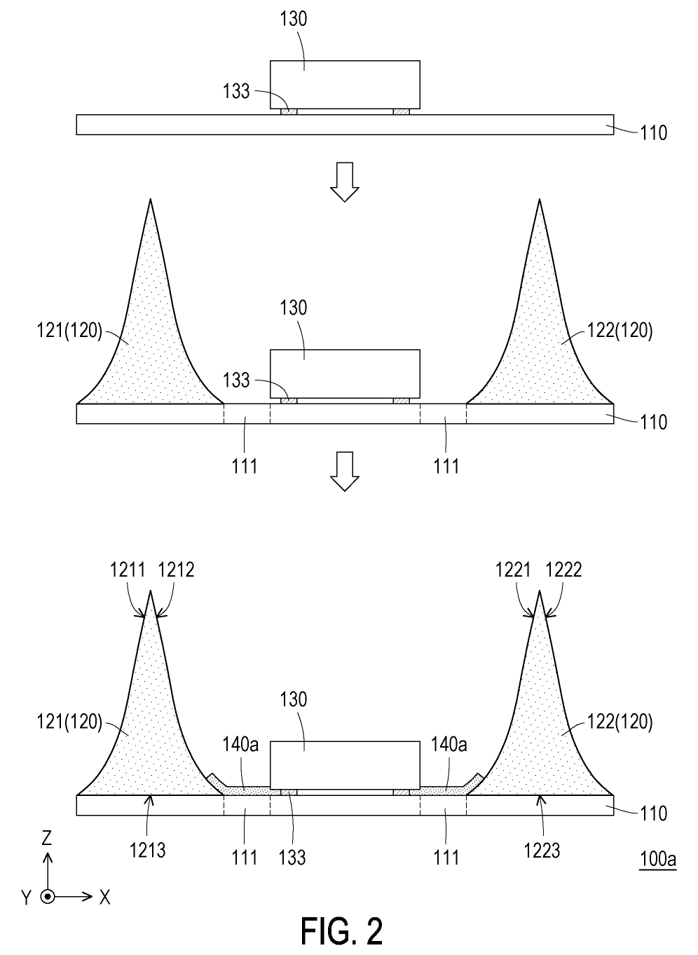

FIG. 2 is a cross-sectional schematic view of a method for manufacturing an electronic device according to a second embodiment of the present disclosure, similar to the electronic device 100 of FIG. 1D. The difference is that, the reflective material layer 140a does not overlap with a portion of the blocking wall 120, and the step of forming the reflective material layer 140a is performed after the step of disposing the blocking wall 120.

Specifically, please refer to FIG. 2, in the present embodiment, the method of manufacturing the electronic device 100a may include, but is not limited to, the following steps: First, providing a substrate 110 and disposing a light-emitting unit 130 on the substrate 110, wherein the light-emitting unit 130 may expose a portion of the substrate 110. Next, disposing a blocking wall 120 on the substrate 110, wherein the blocking wall 120 and the light-emitting unit 130 may expose a portion 111 of the substrate 110. Finally, forming a reflective material layer 140aon the substrate 110, such that the reflective material layer 140a may cover the portion 111 of the substrate 110 exposed by the blocking wall 120 and the light-emitting unit 130. At this point, the electronic device 100aof the present embodiment is substantially manufactured.

In the present embodiment, since the step of forming the reflective material layer 140a is performed after the step of disposing the blocking wall 120, the reflective material layer 140a may extend to the another side surface 1212 of the first portion 121 and the side surface 1221 of the second portion 122 of the blocking wall 120, and the reflective material layer 140a may not be formed between the bottom surface of the blocking wall 120 and the substrate 110 (that is, between the bottom surface 1213 of the first portion 121 and the substrate 110, and between the bottom surface 1223 of the second portion 122 and the substrate 110).

In the present embodiment, the reflective material layer 140a may cover the portion 111 of the substrate 110 that is not covered by the blocking wall 120 and the light-emitting unit 130. The reflective material layer 140a may overlap with the portion 111 of the substrate 110 in the normal direction Z of the substrate 110, and the reflective material layer 140a may not completely overlap with the blocking wall 120 in the normal direction Z of the substrate 110. Thus, the light emission efficiency of the light-emitting unit 130 may be improved, the cost may be reduced, or the material used for forming the reflective material layer may be saved.

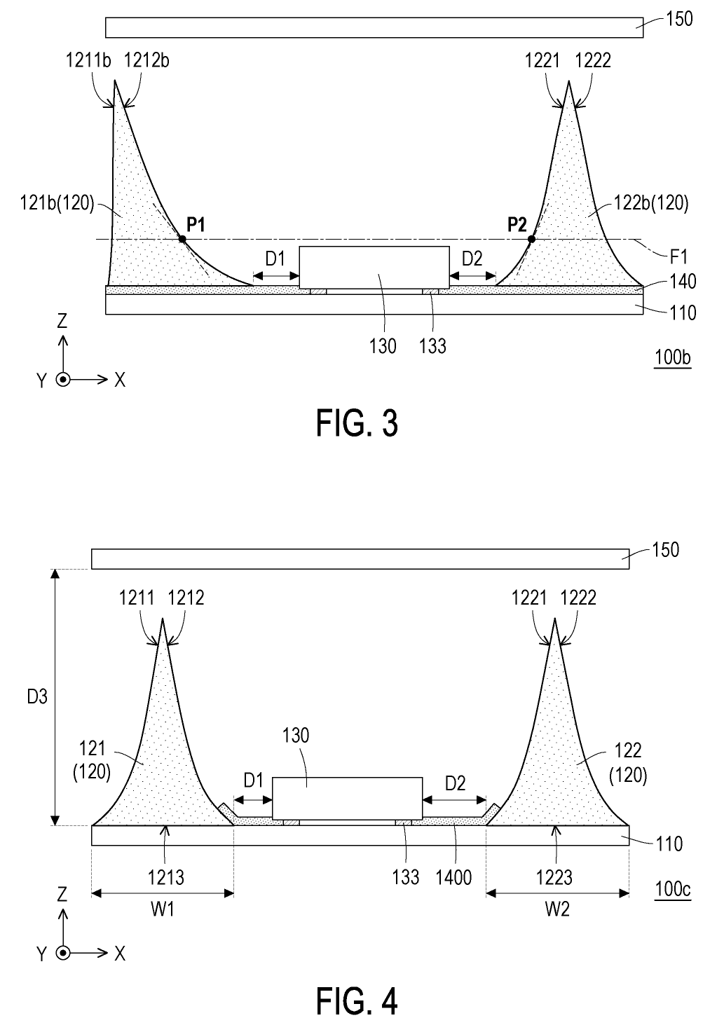

FIG. 3 is a cross-sectional schematic view of an electronic device according to a third embodiment of the present disclosure, similar to the electronic device 100 of FIG. 1B. The difference is that, the absolute value of the slope of the another side surface 1212b of the first portion 121b is not equal to the absolute value of the slope of the side surface 1221 of the second portion 122.

Specifically, please refer to FIG. 3, the side surface 1211b of the first portion 121b may be a planar surface, and the another side surface 1212b of the first portion 121b, as well as the side surface 1221 and the another side surface 1222 of the second portion 122, may be curved surfaces.

In the present embodiment, along the same reference line (for example, reference line F1), the absolute value of the slope of the another side surface 1212b of the first portion 121b may be less than the absolute value of the slope of the side surface 1221 and the absolute value of the slope of the another side surface 1222 of the second portion 122, and the absolute value of the slope of the side surface 1221 of the second portion 122 may be equal to the absolute value of the slope of the another side surface 1222. In other words, in the present embodiment, the curvature of the another side surface 1212b of the first portion 121b may be greater than the curvature of the side surface 1221 and the curvature of the another side surface 1222 of the second portion 122, and the curvature of the side surface 1221 of the second portion 122 may be equal to the curvature of the another side surface 1222.

For example, as shown in FIG. 3, the absolute value of the slope at point P1 is less than the absolute value of the slope at point P2 along the same reference line F1.

In addition, in the present embodiment, the first minimum distance D1 between the first portion 121b and the light-emitting unit 130 may be equal to the second minimum distance D2 between the light-emitting unit 130 and the second portion 122.

FIG. 4 is a cross-sectional schematic view of an electronic device according to a fourth embodiment of the present disclosure, similar to the electronic device 100a of FIG. 2. The difference is that, the first minimum distance D1 is not equal to the second minimum distance D2.

Specifically, please refer to FIG. 4, in the present embodiment, the first minimum distance D1 between the first portion 121 and the light-emitting unit 130 may be greater than or equal to 10 micrometers, and the second minimum distance D2 between the light-emitting unit 130 and the second portion 122 may be greater than or equal to 10 micrometers. The first minimum distance D1 may be less than the second minimum distance D2, and the first minimum distance D1 and the second minimum distance D2 may be less than 6 times the third minimum distance D3 between the diffuser plate 150 and the substrate 110. That is, D1, D2, and D3 may satisfy the following formula: 10μm ≤ D1 < D2 < 6×D3.

In addition, in the present embodiment, along the same reference line, the absolute value of the slope of the side surface 1211 of the first portion 121 may be equal to the absolute value of the slope of the another side surface 1212, the absolute value of the slope of the side surface 1221 of the second portion 122 may be equal to the absolute value of the slope of the another side surface 1222, and the absolute value of the slope of the another side surface 1212 of the first portion 121 may be equal to the absolute value of the slope of the side surface 1221 of the second portion 122.

In addition, in the present embodiment, the bottom surface 1213 of the first portion 121 has a width W1, the bottom surface 1223 of the second portion 122 has a width W2, and the width W1 is equal to the width W2, but is not limited thereto. Herein, the width W1 may be the distance measured along direction X on the bottom surface 1213 of the first portion 121, and the width W2 may be the distance measured along direction X on the bottom surface 1223 of the second portion 122.

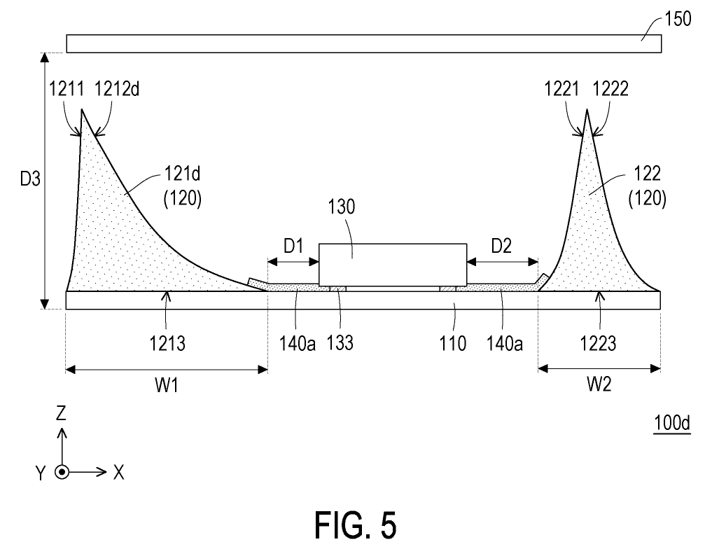

FIG. 5 is a cross-sectional schematic view of an electronic device according to a fifth embodiment of the present disclosure, similar to the electronic device 100a of FIG. 2. The difference is that, the first minimum distance D1 is not equal to the second minimum distance D2, and the absolute value of the slope of the another side surface 1212d of the first portion 121d is not equal to the absolute value of the slope of the side surface 1221 of the second portion 122.

Specifically, please refer to FIG. 5, in the present embodiment, the first minimum distance D1 between the first portion 121d and the light-emitting unit 130 may be greater than or equal to 10 micrometers, and the second minimum distance D2 between the light-emitting unit 130 and the second portion 122 may be greater than or equal to 10 micrometers. The first minimum distance D1 may be less than the second minimum distance D2, and the first minimum distance D1 and the second minimum distance D2 may be less than 6 times the third minimum distance D3 between the diffuser plate 150 and the substrate 110. That is, D1, D2, and D3 may satisfy the following formula: 10μm ≤ D1 < D2 < 6×D3.

In addition, in the present embodiment, along the same reference line, the absolute value of the slope of the side surface 1211 of the first portion 121d may not be equal to the absolute value of the slope of the another side surface 1212d, the absolute value of the slope of the side surface 1221 of the second portion 122 may be equal to the absolute value of the slope of the another side surface 1222, and the absolute value of the slope of the another side surface 1212d of the first portion 121d may be less than the absolute value of the slope of the side surface 1221 of the second portion 122. That is, in the present embodiment, the curvature of the side surface 1211 of the first portion 121d may not be equal to the curvature of the another side surface 1212d, the curvature of the side surface 1221 of the second portion 122 may be equal to the curvature of the another side surface 1222, and the curvature of the another side surface 1212d of the first portion 121d may be greater than the curvature of the side surface 1221 of the second portion 122.

In addition, in the present embodiment, please refer to the cross-sectional view of FIG. 5, the bottom surface 1213 of the first portion 121d has a width W1, the bottom surface 1223 of the second portion 122 has a width W2, and the width W1 is greater than the width W2, but is not limited thereto. Herein, the width W1 may be the distance measured along the direction X on the bottom surface 1213 of the first portion 121d, and the width W2 may be the distance measured along the direction X on the bottom surface 1223 of the second portion 122.

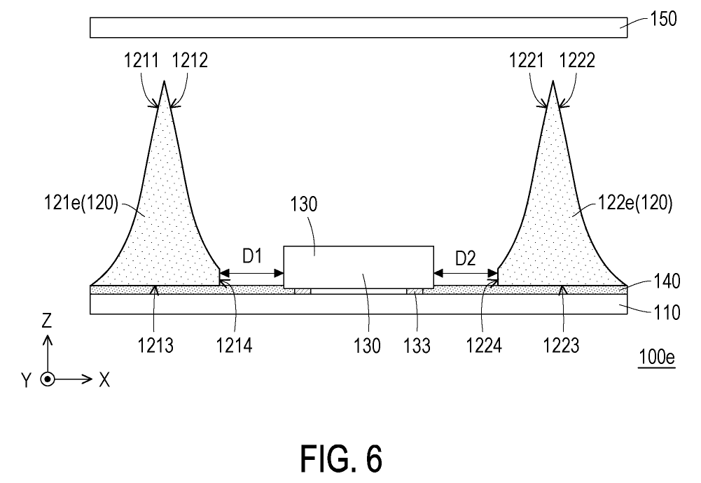

FIG. 6 is a cross-sectional schematic view illustrating an electronic device according to a sixth embodiment of the present disclosure, similar to the electronic device 100 of FIG. 1B. The difference is that, the another side surface 1212 of the first portion 121e has a chamfer-formed processed surface 1214 adjacent to the bottom surface 1213, and the side surface 1221 of the second portion 122e has a chamfer-formed processed surface 1224 adjacent to the bottom surface 1223.

Specifically, please refer to FIG. 6, the side surface 1211 of the first portion 121e and the another side surface 1222 of the second portion 122e are both curved surfaces. A portion of the another side surface 1212 of the first portion 121e adjacent to the bottom surface 1213 and a portion of the side surface 1221 of the second portion 122e adjacent to the bottom surface 1223 are cut off to form chamfers, but are not limited thereto. The chamfer may also be directly formed through rolling, stamping, molding, or injection. The main purpose is to cause the side surface of the blocking wall (for example, the another side surface 1212 of the first portion 121e) to retreat in a direction away from the light-emitting unit 130, thereby adjusting the distance between the blocking wall and the light-emitting unit. In other words, the another side surface 1212 of the first portion 121e and the side surface 1221 of the second portion 122e are both discontinuous surfaces composed of curved surfaces and chamfers. For example, the absolute value of the slope of the another side surface 1212 of the first portion 121e gradually decreases from the end far from the substrate 110 toward the another end adjacent to the substrate 110, and then increases again when extending to the chamfer-formed processed surface 1214. Therefore, the position where the slope reverses is the turning point of the discontinuous surface. In some embodiments, the chamfer-formed processed surface may be a planar surface or a curved surface.

In the present embodiment, when the height of the blocking wall 120 cannot be adjusted, the distance between the blocking wall 120 and the light-emitting unit 130 may first be adjusted so that the light rays with emission angles from 10 degrees to 35 degrees may be reflected by the blocking wall 120. Subsequently, by forming chamfers at the portion of the another side surface 1212 adjacent to the bottom surface 1213 and the portion of the side surface 1221 adjacent to the bottom surface 1223, it is ensured that the first minimum distance D1 and the second minimum distance D2 may be greater than or equal to 10 micrometers.

What is claimed is:

1. An electronic device, comprising:
a substrate;
a blocking wall disposed on the substrate and having at least one opening; and
a light-emitting unit disposed in the at least one opening and having a first side and a second side opposite to the first side;
wherein in a cross-section the blocking wall has a first portion closest to the first side and a second portion closest to the second side,
wherein along a direction perpendicular to a normal direction of the substrate, a first minimum distance from the first portion to the first side is less than a second minimum distance from the second portion to the second side.

2. The electronic device according to claim 1, further comprising:
a diffuser plate disposed on the blocking wall,
wherein the first minimum distance is D1, the second minimum distance is D2, and a third minimum distance between the diffuser plate and the substrate along the normal direction of the substrate is D3, satisfying the following formula: 10μm ≤ D1 < D2 < 6×D3.

3. The electronic device according to claim 1, wherein a side surface of the first portion facing the light-emitting unit is a curved surface, and a side surface of the second portion facing the light-emitting unit is a curved surface.

4. The electronic device according to claim 3, wherein along a reference line perpendicular to the normal direction of the substrate, an absolute value of a slope at an intersection of the side surface of the first portion with the reference line is less than or equal to an absolute value of a slope at an intersection of the side surface of the second portion with the reference line.

5. The electronic device according to claim 4, wherein the absolute value of the slope of the side surface of the first portion and the absolute value of the slope of the side surface of the second portion gradually decrease from an end far from the substrate toward another end adjacent to the substrate.

6. The electronic device according to claim 3, wherein the side surface of the first portion has a chamfer near a bottom surface, and the side surface of the second portion has a chamfer near a bottom surface.

7. The electronic device according to claim 3, wherein another side surface of the first portion facing away from the light-emitting unit is a curved surface, and another side surface of the second portion facing away from the light-emitting unit is a curved surface.

8. The electronic device according to claim 7, wherein an absolute value of a slope of the side surface of the first portion is equal to an absolute value of a slope of the another side surface of the first portion, and an absolute value of a slope of the side surface of the second portion is equal to an absolute value of a slope of the another side surface of the second portion.

9. The electronic device according to claim 7, wherein an absolute value of a slope of the side surface of the first portion is less than an absolute value of a slope of the another side surface of the first portion, and an absolute value of a slope of the side surface of the second portion is equal to an absolute value of a slope of the another side surface of the second portion.

10. The electronic device according to claim 1, further comprising:
a reflective material layer disposed on the substrate and not overlapping with at least a portion of the blocking wall.

11. The electronic device according to claim 10, wherein the reflective material layer covers a portion of the substrate not covered by the blocking wall and the light-emitting unit.

12. The electronic device according to claim 1, wherein further comprising:
a reflective material layer disposed on the substrate and having an opening overlapping with the light-emitting unit.

13. The electronic device according to claim 12, wherein the reflective material layer covers a portion of the substrate not covered by the blocking wall and the light-emitting unit.

14. The electronic device according to claim 1, wherein a width of a bottom surface of the first portion is equal to a width of a bottom surface of the second portion.

15. The electronic device according to claim 1, wherein a width of a bottom surface of the first portion is greater than a width of a bottom surface of the second portion.

16. An electronic device, comprising:
a substrate;
a blocking wall disposed on the substrate and having at least one opening; and
a light-emitting unit disposed in the at least one opening and having a first side and a second side opposite to the first side;
wherein in a cross-section, the blocking wall has a first portion closest to the first side and a second portion closest to the second side,
wherein along a reference line perpendicular to a normal direction of the substrate, an absolute value of a slope at an intersection of a side surface of the first portion facing the light-emitting unit and the reference line is less than an absolute value of a slope at an intersection of a side surface of the second portion facing the light-emitting unit and the reference line.

17. The electronic device according to claim 16, wherein along a direction perpendicular to the normal direction of the substrate, a first minimum distance from the first portion to the first side is less than or equal to a second minimum distance from the second portion to the second side.

18. The electronic device according to claim 17, further comprising:
a diffuser plate disposed on the blocking wall,
wherein the first minimum distance is D1, the second minimum distance is D2, and a third minimum distance between the diffuser plate and the substrate along the normal direction of the substrate is D3, satisfying the following formula: 10μm ≤ D1 ≤ D2 < 6×D3.

19. The electronic device according to claim 16, further comprising:
a reflective material layer disposed on the substrate and not overlapping with at least a portion of the blocking wall.

20. The electronic device according to claim 19, wherein the reflective material layer covers a portion of the substrate not covered by the blocking wall and the light-emitting unit.
